(19) United States
(12) Patent Application Publication
(10) Pub. No.: US 2007/0232055 A1
(43) Pub. Date: Oct. 4, 2007

(54) Methods and Apparatuses for Applying a Protective Material to an Interconnect Associated with a Component

(76) Inventors: Richard Earl Corley, Richmond, KY (US); Shelby Wayne Dennis, Richmond, KY (US); Edgar Colin Diaz, Chihuahua (MX); Richard Leo Hubert, Lexington, KY (US); Jonathan Harold Laurer, Boone, NC (US); Tu Phan, Lexington, KY (US); George Allan Ping, Berea, KY (US); Jeanne Marie Saldanha Singh, Lexington, KY (US); Mary Claire Smoot, Lexington, KY (US); Paul Timothy Spivey, Lexington, KY (US)

Correspondence Address: LEXMARK INTERNATIONAL, INC.;INTELLECTUAL PROPERTY LAW DEPARTMENT, 740 WEST NEW CIRCLE ROAD, BLDG. 082-1, LEXINGTON, KY, 40550-0999, US

(21) Appl. No.: 11/423,720

(22) Filed: Jun. 13, 2006

Related U.S. Application Data
(60) Provisional application No. 60/744,049, filed on Mar. 31, 2006.

(51) Int. Cl. H01L 21/4763

(52) U.S. Cl. 438/618

(57) ABSTRACT

Methods and apparatuses for applying a protective material to an interconnect associated with a component. One such method involves placing a stencil in close proximity to an interconnect that extends over a cavity. An amount of protective material is placed on the stencil. A wiper is passed across the stencil. The wiper has an angle of attack of less than 50 degrees. At least a desired thickness of protective material is applied to the interconnect.

This application claims the benefit of U.S. Provisional Application No. 60/744,049, filed Mar. 31, 2006.

### FIELD OF THE INVENTION

The present invention relates to methods and apparatuses for applying a protective material, such as an encapsulant, to an interconnect associated with a component, and more specifically, in one exemplary embodiment, to methods and apparatuses for applying an encapsulant to TAB beams on inkjet printheads using stencil printing techniques.

### BACKGROUND OF THE INVENTION

There are many types of components and associated interconnects that are used in demanding environments. For example, Tape Automated Bonding (TAB) interconnects (e.g., leads and bonds) that are used to connect to actuator chips in ink jet printheads can be subjected to mechanical action from a wiper, thermal effects, and/or chemical effects, such as those due to exposure to the corrosive inks. As such, the leads and bonds used in these applications should be protected. Typically, this is accomplished by covering the leads and bonds with a layer of protective material, such as a polymer based coating (e.g., an epoxy based thermal or UV curable adhesive), that seals against, for example, a chip, nozzle plate edge, flexible circuit, leads connecting the flexible circuit to the chip, other protective materials, chip pocket, and an adhesive used to attach the chip to the chip pocket, thereby coating and helping protect the leads and bonds from corrosion, thermal and/or mechanical action.

It is known in the art to form the aforementioned protective layer using a discharge needle. While this method has produced generally acceptable results in the past, there have been problems that need to be addressed. Recently, it has been found that stencil printing techniques are capable of producing better overall results than discharge needle techniques. In particular, commonly assigned U.S. Ser. No. 10/679,070, describes a method of applying a protective material using stencil printing techniques. In particular, stencil printing may be used to provide more accurately placed, thinner (but sufficient) layers of protective material, which may afford for tighter print gaps and better print quality, for example.

While stencil printing has been conventionally used in other applications, particularly those with substantially planar surfaces, there are complications that arise when working with, for example, electronic components and/or their leads in that, due to the design of the device or apparatus incorporating the same, there may be a cavity beneath the component and/or the leads that are to be coated. For example, referring to FIG. 10, a chip 18 may be placed in a chip pocket 12 on a device (e.g., where it is adhesively attached in the chip pocket) wherein a cavity C exists between an edge of the chip and a wall of the chip pocket. It may be desirable for a lead or leads 24 to extend over this cavity C in order to connect the chip 18 with another component or device. In some cases, while a coating is applied to leads 24, the coating might sink in-between adjacent ones of the leads and leave an insufficiently thin coating on the leads. This condition is referred to herein as “slumping.” Amongst other things, slumping can reduce corrosion protection because of the diminished thickness of the protective material over the leads 24 (typically, a protective material should be about 0.003 inches thick to ensure adequate corrosion protection).

### SUMMARY OF THE INVENTION

In exemplary embodiments, the present invention provides methods and apparatuses for applying a protective material to an interconnect associated with a component. One such method involves placing a stencil in close proximity to an interconnect that extends over a cavity. An amount of protective material is placed on the stencil. A wiper is passed across the stencil. The wiper has an angle of attack of less than 50 degrees. At least a desired thickness of protective material is applied to the interconnect.

In another embodiment of the present invention, a stencil is placed in close proximity to an interconnect that extends over a cavity. An amount of protective material is placed on the stencil. A wiper is passed across the stencil. The wiper has an angle of attack of less than 50 degrees and a hardness of less than about 70 durometer on a Shore D scale (or equivalent). At least a desired thickness of protective material is applied to the interconnect.

In yet a further embodiment of the invention, a stencil is placed in close proximity to an interconnect that extends over a cavity. An amount of protective material is placed on the stencil. The protective material has a viscosity of between about 30,000 cps and about 240,000 cps. A wiper is passed across the stencil. The wiper has an angle of attack of less than 50 degrees and a hardness of less than about 90 durometer on a Shore D scale. A pressure is applied to the protective material by the wiper while it is passing across the stencil. The pressure is between about 0 to about 160 psi. At least a desired thickness of protective material is applied to the interconnect.

Still further embodiments will be apparent to those of ordinary skill in the art and are considered to be within the scope of the invention.

### BRIEF DESCRIPTION OF THE DRAWINGS

FIG. 1 shows a representational view of a stencil application of a protective material to printhead electronic chip leads;

FIG. 2 shows a representational view of a prior art stencil application of a protective material to printhead electronic chip leads;

FIG. 3 shows a representational view of a squeegee for use in applying a protective material to printhead electronic chip leads in accordance with an exemplary embodiment of the present invention;

FIG. 4 shows a representational view of a prior art squeegee for use in applying a protective material to electronic chip leads;

FIG. 5 shows a representational view of a squeegee for use in applying a protective material to electronic chip leads in accordance with an exemplary embodiment of the present invention;

FIG. 6 shows a representational view of a squeegee with a rigid backer for use in applying a protective material to electronic chip leads in accordance with an exemplary embodiment of the present invention;

FIG. 7 shows a representational view of a first pass squeegee for use in applying a protective material to electronic chip leads in accordance with an exemplary embodiment of the present invention;

FIG. 8 shows a representational view of a second pass squeegee for use in applying a protective material to electronic chip leads in accordance with an exemplary embodiment of the present invention;

FIG. 9 shows a representational view of dual squeegees for use in applying a protective material to electronic chip leads in accordance with an exemplary embodiment of the present invention;

FIG. 10 shows a partial cross-sectional view of a prior art TAB assembly with the chip in a chip pocket, prior to application of a protective material; and

FIG. 11 shows a partial cross-sectional view of an exemplary TAB assembly with the chip in a chip pocket and protective material applied in accordance with an exemplary embodiment of the present invention.

### DETAILED DESCRIPTION OF EXEMPLARY EMBODIMENTS

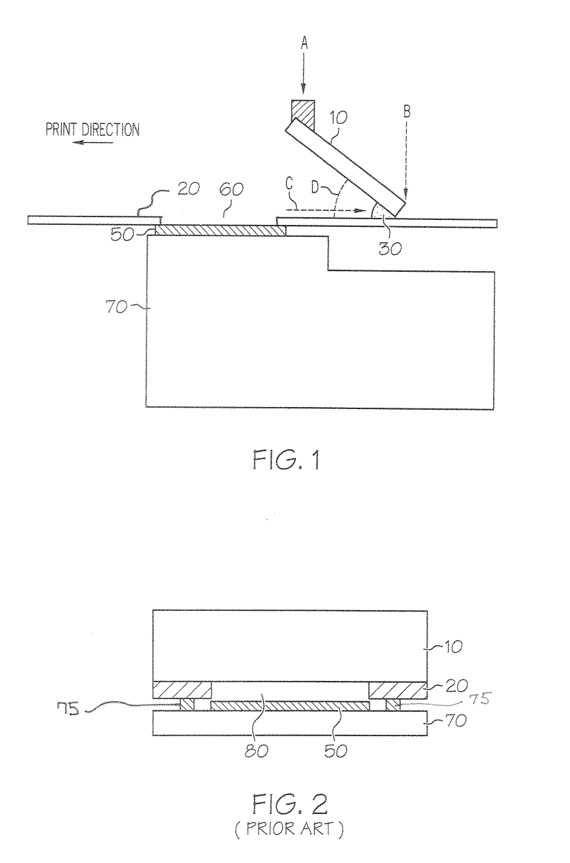

Referring now to FIG. 1, an exemplary embodiment is presented wherein the component is a combination of an actuator chip and a nozzle plate, which is sometimes referred to collectively as a printhead chip. In particular, the exemplary embodiment involves a printhead chip that has been TAB bonded to a flexible circuit, referred to hereinafter as a TAB circuit, wherein the combination of the TAB circuit and printhead chip will be referred to hereinafter as a TAB assembly 50. Conventionally, the interconnects between the TAB circuit and the printhead chip are known as TAB beams (which are an example of leads), wherein the TAB beams extend between an edge of the flexible circuit and an edge of the printhead chip. As can be understood by one of ordinary skill in the art, aspects of the present invention can also be extended to use with other components and/or interconnects.

In an illustrative embodiment, it may be desired to attach the TAB assembly 50 to a printhead body 70. For example, referring to FIG. 11, the body 70 may be provided with a recessed area 12, conventionally referred to as a chip pocket, generally surrounded by a substantially planar area 14 (which may have a plurality of vent channels therein) referred to hereinafter as a deck. An adhesive 16 and/or adhesives may be applied in the chip pocket 12 and/or to the deck 14 to attach the TAB assembly 50 to the body 70.

Generally, the adhesive 16 applied to the chip pocket is referred to as a die attach adhesive and is used to attach a printhead chip 18 to the body 70. In an exemplary embodiment, the adhesive 16 is also applied to locations on the deck 14 (see, e.g., FIG. 10). Adhesive 16 and a pressure sensitive adhesive (PSA) (not shown) on the deck are used to attach and seal a TAB circuit 22 to the body 70.

Adhesive 16 should adhere to the various materials it is supposed to come into contact with (e.g., printhead body material and chip material). Adhesive 16 should also be resistant to the corrosive component(s) of any fluid(s) which is to be ejected by the printhead chip 18. One suitable form of such an adhesive for use in inkjet printheads is an epoxy-based adhesive available from Emerson & Cuming of Billerica, Mass. under the trade name ECCOBOND 3193-17.

As will be described below, a protective material 30, such as a thermally curable epoxy adhesive, is stencil printed over beams 24 connecting the printhead chip 18 to the TAB circuit 22. In an exemplary embodiment, the protective material 30 might have a viscosity in the range of about 30,000 cps to about 240,000 cps, with a thixotropic index of 1 to 10. The protective material 30 should adhere to the various materials it is supposed to come into contact with and it should be resistant to the corrosive component(s) of any fluid(s) which is to be ejected by the printhead chip 18. Exemplary materials that protective material 30 should be able to adhere to might include, but are not limited to, gold-coated TAB beams, polyimide nozzle plates and TAB circuit materials, silicon chip edges, epoxy die attach adhesives, and PPO and/or PPE (modified polyphenylene oxide and polyphenylene ether), such as NORYL (which may be the material that forms the body 70).

Exemplary protective materials may include thermal cure epoxy adhesives such as Epibond 7275 from Huntsman Advanced Chemicals Inc. and EMS 502-39-1 from EMS Inc. Other alternatives may include, for example, a UV radiation curable urethane acrylate material such as ECCOBOND UV9000, which is commercially available from Emerson & Cuming, and Emcast 708 which is available from EMI Inc. Although, in some embodiments, the die attach adhesive may be cured prior to applying the protective material, an exemplary embodiment will be discussed below wherein it is assumed that the die attach adhesive and the protective material are co-cured, which may advantageously combine process steps during manufacturing of a printhead.

Referring again to FIG. 1, with respect to stencil printing protective material 30, the basic components comprise a wiper, such as squeegee 10, and a stencil 20. Stencil 20 can be made of various materials. Particularly useful examples include, but are not limited to plastics and stainless steels. Specific examples of useful plastics include but are not limited to, polyimides and fluoropolymer coated polyimides. In the illustrated embodiment, stencil 20 may have a thickness in the range of from about 0.001 inches to about 0.015 inches, such as in the range of about 0.003 to about 0.006 inches. The distance between the stencil 20 and a top of the interconnect(s)/component(s) (e.g., TAB assembly 50/body 70) to be coated should be in the range of from 0 to about 0.1 mm, such as from about 0.03 to about 0.07 mm.

In practice, a force A is exerted on squeegee 10 to bring it in contact with a surface of stencil 20. Force A translates into a pressure (force per unit of contact area) on the protective material 30 in contact with the squeegee 10. Generally, enough force A should be exerted on squeegee 10 so that it fills and packs protective material 30 into any cavity C that may be beneath leads 24 (see FIG. 11) and keeps the contacted surface of stencil 20 free of protective material 30. For example, in exemplary embodiments of the present invention, a force A should be applied to cause a pressure on the protective material 30 in the range of less than about 160 psi, in particular in the range of from about 40 to about 80 psi (e.g., 65 psi). Depending on the angle D between a wiping surface of squeegee 10 and the contacted surface of stencil 20 (which defines the “angle of attack” in the illustrated embodiment), squeegee 10 will generally transfer force A to the protective material 30 and the contacted surface of stencil 20 as the squeegee is being passed across the stencil, with the transferred force being defined by component vectors B and C. The force and angle of attack allow for shear thinning of the protective material and filling of material into the cavity C.

Referring again to FIG. 11, in a first set of exemplary embodiments, combinations of TAB assemblies 50 and printhead bodies 70 are used such that, when attached, a portion of the TAB circuit 22 generally overhangs a cavity C (e.g., between a wall of the chip pocket and an edge of the printhead chip) by less than about 0.6 mm (e.g., in the range of about 0.2 mm wide to about 0.4 mm wide), with the width of the chip pocket to the chip edge being in the range of about 0.2 mm to about 0.6 mm (e.g., about 0.4 mm). Conventionally, in most industries, an angle D of about 50 degrees has been used when stencil printing. Against this conventional wisdom, when stencil printing on discontinuous surfaces, such as those that have pockets or trenches such as described above, it has been determined that an angle D less than 50 degrees should be used. For example, for packing in an exemplary embodiment, it has been determined that an angle D in the range of about 10 degrees to about 40 degrees should be used, such as an angle in the range of about 15 degrees to about 35 degrees.

For example, in an illustrative embodiment, in the range of about 14 to about 18 mg (e.g., about 16 mg) of die attach adhesive 16 is dispensed in a chip pocket 12 of a body 70. The dimensions of an exemplary chip pocket 12 are from about 10.37 mm to about 30.6 mm long, from about 3.37 mm to about 7.6 mm wide, and from about 0.4 mm to about 0.5 mm deep. Typically, in the range of about 6 mg to about 10 mg (e.g., about 8 mg, but in some embodiments, as much as 16 mg) of the adhesive 16 is also dispensed on a deck 14 of body 70 (e.g., at locations about 0.1 mm to 1 mm from the edge of the pocket, such as about 0.65 mm from the edge of the pocket). A chip 18, such as one having a length of about 10 mm to about 30 mm, and a width of about 3 mm to about 7 mm, is placed into pocket 12. According to an exemplary embodiment, the separation distance between chip 18 and a wall of pocket 12 is circumferentially about 0.37 mm to about 0.6 mm (e.g., about 0.42 mm). Accordingly, an exemplary flexible circuit 22 connected to chip 18 overhangs pocket 12 in the range of about 0.2 mm to about 0.6 mm (e.g., about 0.4 mm).

Referring back to FIG. 1, a squeegee 10 is oriented such that an angle D is in the range of about 20 degrees to about 35 degrees. For purposes of illustration, such a squeegee may comprise a 10 cm polymeric polyurethane squeegee having a hardness of about 50 durometers on a Shore D scale (or equivalent), although other squeegees may be used with embodiments of the present invention. For example, a squeegee 10 may also be made of materials such as, but not limited to, polyolefins (e.g., polyethylenes and polypropylenes), stainless steels, and fluoropolymers (such as PTFE), for example.

Thus, in operation with the previously described exemplary embodiment, as squeegee 10 is passed across stencil 20 (e.g., in the range of about 25 mm/s to about 125 mm/s, such as about 70 mm/s), with protective material 30 being replenished at a rate of about 0.01 to about 0.04 grams per part (e.g., about 0.02 grams per part), the protective material shear thins and is delivered through an opening(s) 60 in stencil 20 onto the TAB beams and into the pocket. When a force A is also placed on squeegee 10, a pressure is transferred to protective material 30 in contact with the squeegee in the range of about 0 to about 160 psi (e.g., between about 40 psi and about 80 psi), as described above (and which is also transferred to the TAB assembly 50, body 70 and adhesives in the pocket and on the deck).

Referring back to FIG. 11, in an embodiment wherein the adhesive 16 is still uncured, this causes the adhesive 16 in the pocket 12 to displace into a cavity C between an edge of the printhead chip 18 and a wall of the chip pocket (over which the TAB beams and TAB circuit extend) while the protective material 30 is being delivered. When the force A is relieved, the TAB assembly 50 and die attach adhesive 16 re-stabilize. Conventionally, this leads to problems like slumping. When using an angle D as set forth above with the exemplary embodiment, however, an amount of protective material 30 is delivered by squeegee 10 that is sufficient to afford for the portion of the protective material that is sheared into the cavity, while still providing a thick enough coating on the TAB beams to afford the desired protection (as the angle D is decreased, the hydrodynamic pressure generated by the protective material 30 is increased).

Ideally, the thickness of stencil 20 would determine the overall thickness of the coating of protective material 30 on the TAB beams and/or the printhead chip (referred to hereinafter as the thickness of the protective layer). However, in practice, the thickness of the protective layer 30 is impacted by a variety of additional factors, some process oriented, others design driven. These additional factors can include, for example stencil material and shape; squeegee material, modulus/hardness, speed, angle of attack D, and the force on squeegee; part design; and protective material rheology.

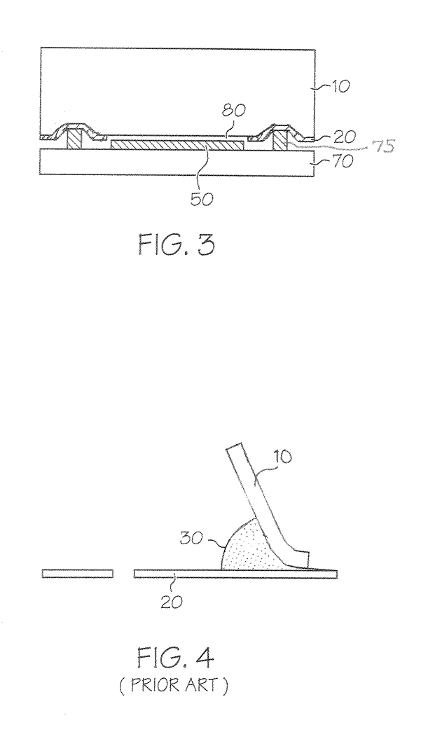

For example, as shown in FIGS. 2 and 3, a body 70 may be equipped with a barrier 75, such as one that can be used to help prevent a printer maintenance wiper from damaging the TAB assembly 50. Such a barrier 75 may make it difficult to apply a desired thickness of protective material 30 on the leads/components of the TAB assembly 50 using prior art stencil printing techniques. For example, as can be seen in FIG. 2, using a prior art approach, it can be difficult to position a stencil 20 as close to the TAB assembly 50 as might be desired. Given the undesirably large gap 80, the protective material 30 is generally thicker than might be wanted.

Accordingly, the gap 80 may be controlled by selecting an appropriate squeegee and/or stencil material. For example, a stainless steel squeegee may not conform to the barriers 75. Accordingly, as shown in FIG. 3, in an exemplary embodiment of the present invention, a squeegee 10 and/or stencil 20 are chosen such that they will generally comply with the barriers 75, and reduce gap 80.

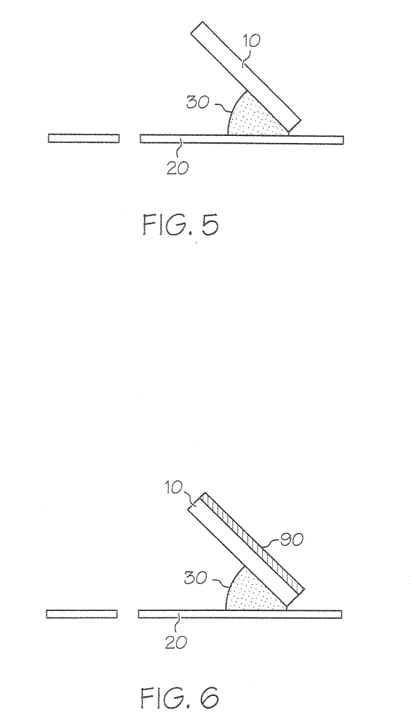

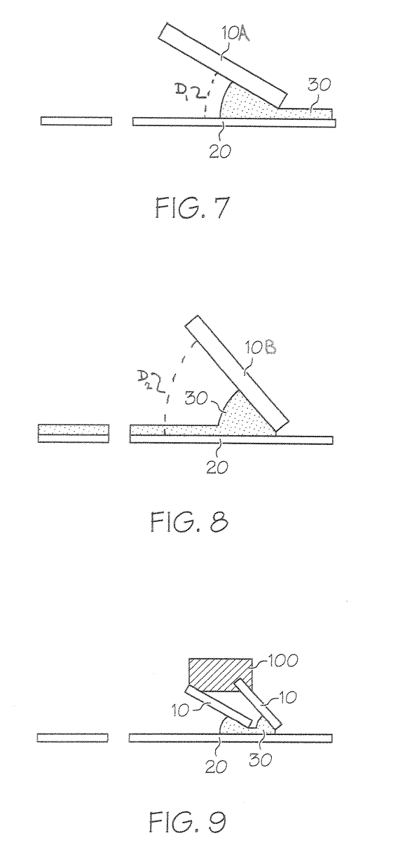

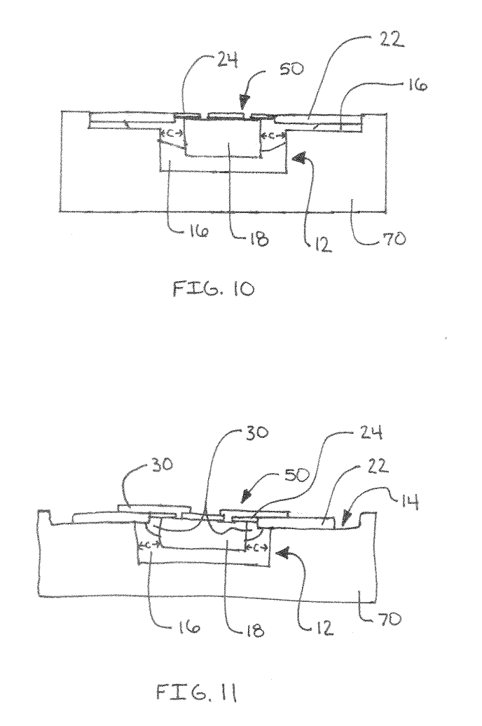

Additionally and/or alternatively, a squeegee 10 having a specifically determined hardness (as shown in FIG. 5) or a squeegee 10 having a rigid backing 90 applied thereto to achieve a specifically determined hardness (as shown in FIG. 6) may be used to prevent undesirable deflection of squeegee 10 (along the height), which can also lead to undesirable protective layer thickness. Such squeegees represent improvements over prior art squeegees (as shown in FIG. 4) which were susceptible to deflection, particular when using small angles of attack (thereby causing a consistent layer of protective material 30 residue to be left on the top of the stencil 20, and potentially excessive deposition of protective material 30 over the surface of TAB assembly 50). More specifically, the engineered hardness of the squeegees 10 as shown in FIGS. 5 and 6 is established such that the deflection of the squeegee for the particular application allows the squeegee to wipe the stencil 20 clean, while still allowing the squeegee to deposit the desired volume and height of protective material 30 through the opening 60 in a single pass.

It should be noted, however, that too high of a stiffness modulus (i.e hardness) of the squeegee 10 can result in the squeegee and the stencil 20 not having enough conformance there between, thereby preventing the desired amount of protective material 30 from being deposited through the stencil. As such, the hardness of the stencil 20 should be specifically chosen to take into account the width and material properties of the stencil itself, as well as the rheological properties of the protective material 30 being deposited.

Accordingly, it has been found that squeegees 10 having a hardness in the range of about 0-90 durometers on a Shore D scale (or Shore A equivalent, for example), such as in the range of about 40 to about 70 Shore D, might be used in accordance with an exemplary embodiment of the present invention. In some embodiments, a backing material 90 might be used to provide benefits similar to such a desired hardness (e.g., resisting deflection and helping to maintain good stencil-squeegee contact). It has been found that, amongst other materials, polyolefins, polyurethanes, stainless steels, fluoropolymers, ceramics and metals, such as aluminum, stainless steel, and titanium, are acceptable and operable as backing materials 90.

Embodiments in line with the exemplary embodiments described above have been used to apply protective material 30 on TAB assemblies 50/printheads 70 with the resulting protective layer thickness being thinner (but still sufficient) than those produced using conventional dispense technologies. For example, embodiments have been implemented that can provide protective layer thicknesses on the order of from about 0.003 inches to about 0.009 inches (˜about 0.076 mm to about 0.228 mm). This can be advantageously utilized to, for example, provide tighter print gaps (e.g., a distance between a print medium and TAB assembly 50 of body 70) and/or provide better print quality. If a tape is placed over the protective material 30, such as for sealing nozzles, this can also improve the taping flatness and increase the adhesion area of tape to the nozzle plate.

As shown in FIGS. 7 and 8, other exemplary embodiments of the present invention might utilize two or more separate squeegees 10, such as in a multi-pass (e.g., 2-pass) operation. For example, a first squeegee 10A might be selected to appropriately apply a first desired amount of protective material 30 through the stencil 20, such as on a first pass, with a second squeegee 10B being used to apply a second amount of protective material 30, such as on a second pass. In order to get the desired total amount of protective material 30, both the hardness and angle of attack D of both squeegees 10 can be adjusted.

In one such exemplary embodiment, a first squeegee 10A might conform to that previously described with respect to single squeegee embodiments. For example, first squeegee 10A may have a hardness of about 50 durometer on a Shore D scale, and an angle of attack D₁ in the range of about 15 to about 35 degrees (e.g., in the range of about 24 to about 32 degrees). Meanwhile, the second squeegee 10B might be selected such that it has a hardness and angle of attack D₂ capable of ensuring the stencil 20 is wiped substantially clean, and wherein the total amount of protective material 30 deposited by the first squeegee 10A and the second squeegee 10B equals the total amount of protective material desired to be applied to the TAB assembly 50 and/or to any cavities (to sufficiently fill the cavities and encapsulate the leads and/or components being protected). Accordingly, in an exemplary embodiment, the second squeegee 10B should have an angle D₂ that is greater than the angle D₁ associated with the first squeegee 10A, such as on the order of at least 5 degrees greater, but in any event enough of an angle to substantially doctor off any excess material 30 remaining after the pass of the first squeegee, thereby helping control the height of the applied protective material. For example, in the present embodiment, a second squeegee 10B might be used that has a hardness of between about 0 and about 90 durometers on a Shore D (e.g., between about 30 and about 70 Shore D), as was the case with the first squeegee 10A, but with an angle of attack D₂ in the range of about 15 and about 90 degrees (e.g., in the range of about 40 to about 60 degrees).

In yet another embodiment, as shown in FIG. 9, two separate, but mechanically connected, squeegees 10 are used in a single pass operation. Additional mechanical connections might include the use of two squeegees 10 rigidly connected to a mechanical mount 100 (either separately or together) wherein a force-feedback loop is used, offsetting the second squeegee 10B with respect to the first squeegee 10A so that the applied force A from the second squeegee is more, less, or equal to that of the first, as desired. The first and second squeegees may be selected in accordance with the teachings of the embodiments depicted in FIGS. 7 and 8.

Following from the above description and invention summaries, it should be apparent to those of ordinary skill in the art that, while the methods and apparatuses herein described constitute exemplary embodiments of the present invention, the invention contained herein is not limited to this precise embodiment and that changes may be made to such embodiments without departing from the scope of the invention as defined by the claims. For example, although the exemplary embodiments presented herein contemplated only a single pass of a squeegee, multiple passes of a squeegee(s) could be used without departing from the scope of the invention. Additionally, it is to be understood that the invention is defined by the claims and it is not intended that any limitations or elements describing the exemplary embodiments set forth herein are to be incorporated into the interpretation of any claim element unless such limitation or element is explicitly stated. Likewise, it is to be understood that it is not necessary to meet any or all of the identified advantages or objects of the invention disclosed herein in order to fall within the scope of any claims, since the invention is defined by the claims and since inherent and/or unforeseen advantages of the present invention may exist even though they may not have been explicitly discussed herein.

What is claimed is:

1. A method for applying a protective material to an interconnect associated with a component comprising:
placing a stencil in close proximity to an interconnect that extends over a cavity;
placing an amount of protective material on the stencil; and
passing a wiper across the stencil, the wiper having an angle of attack of less than 50 degrees,
wherein at least a desired thickness of protective material is applied to the interconnect.

2. The method of claim 1 wherein the angle of attack is between about 10 degrees and about 40 degrees.

3. The method of claim 1 wherein the angle of attack is between about 15 degrees and about 35 degrees.

4. The method of claim 1 wherein the wiper has a hardness of less than about 90 durometer on a Shore D scale.

5. The method of claim 1 wherein the wiper has a rigid backing.

6. The method of claim 1 wherein the interconnect is a TAB beam extending from a TAB circuit to an ink jet printhead chip, the chip being received in a recessed area having at least one wall, wherein the cavity has a width defined by the distance between an edge of the chip and the at least one wall, and wherein the TAB circuit overhangs the cavity by less than about 0.6 mm.

7. The method of claim 6 wherein the width of the cavity is between about 0.2 to about 0.6 mm.

8. The method of claim 7 wherein the TAB circuit overhangs the cavity by between about 0.2 to about 0.4 mm.

9. The method of claim 8 wherein the cavity has a depth of between about 0.4 mm to about 0.66 mm.

10. The method of claim 6, further comprising applying an adhesive into the recessed cavity area prior to the chip being received in the recessed area, wherein the protective material and the adhesive are cured at substantially the same time.

11. The method of claim 10 wherein the protective material comprises an epoxy.

12. The method of claim 10, wherein the protective material has a viscosity of between about 30,000 cps and about 240,000 cps.

13. The method of claim 12, further comprising applying a force on the wiper, the force creating a pressure of less than about 160 psi on the protective material in contact with the wiper.

14. The method of claim 12, wherein the pressure is between about 40 to about 80 psi.

15. The method of claim 1, wherein the act of passing the wiper across the stencil comprises passing the wiper across the stencil at a speed of between about 25 mm/s to about 125 mm/s.

16. The method of claim 1, further comprising passing a second wiper across the stencil, the second wiper having an angle of attack that is greater than the angle of attack of the first wiper.

17. The method of claim 16 wherein the first and second wipers are mechanically connected.

18. The method of claim 17 wherein the first and second wipers are mounted in a force-feedback loop.

19. A method for applying a protective material to an interconnect associated with a component comprising:
placing a stencil in close proximity to an interconnect that extends over a cavity;
placing an amount of protective material on the stencil; and
passing a wiper across the stencil, the wiper having an angle of attack of less than 50 degrees and a hardness of less than about 90 durometer on a Shore D scale.
wherein at least a desired thickness of protective material is applied to the interconnect.

20. A method for applying a protective material to an interconnect associated with a component comprising:
placing a stencil in close proximity to an interconnect that extends over a cavity;
placing an amount of protective material on the stencil, the protective material having a viscosity of between about 30,000 cps and about 240,000 cps; and
passing a wiper across the stencil, the wiper having an angle of attack of less than 50 degrees and a hardness of less than about 70 durometer on a Shore D scale, and wherein a pressure is applied to the protective material by the wiper while it is passing across the stencil, the pressure being between about 0 to about 160 psi,
wherein at least a desired thickness of protective material is applied to the interconnect.
